(19) United States
(12) Patent Application Publication
(10) Pub. No.: US 2020/0019125 A1
(43) Pub. Date: Jan. 16, 2020

(54) TIMER

(71) Applicant: BAINIAN HU, Cixi (CN)

(72) Inventor: BAINIAN HU, Cixi (CN)

(21) Appl. No.: 16/508,171

(22) Filed: Jul. 10, 2019

Related U.S. Application Data
(60) Provisional application No. 62/696,151, filed on Jul. 10, 2018.

(51) Int. Cl. G04F 1/00; H03K 17/28; G04G 9/12

(52) U.S. Cl. CPC G04F 1/005; G04G 9/12; H03K 17/28

(57) ABSTRACT

A timer may include a power plug, an AC/DC transforming circuit, a relay circuit, a recharging circuit, and a control circuit that includes a relay output, a key input, and an LCD output. The timer may further include a 2.4V battery and a main body. In one embodiment, the key input includes a plurality of buttons. By pressing one or more of these buttons, signals can be transmitted into the key input of the control circuit. The timer may further include an LCD display and the information displayed thereon is transmitted from the LCD output of the control circuit. The power plug can be connected to an AC power source to bring in the power to the AC/DC transforming circuit to generate a 12V DC current that can be transmitted to the recharging circuit to charge the 2.4V battery, as well as providing power to the relay circuit.

### CROSS-REFERENCE TO RELATED APPLICATIONS

This application claims priority under 35 U.S.C. § 119 (e) to U.S. Provisional Patent Application Ser. No. 62/696,151, filed on Jul. 10, 2019, the entire contents of which are hereby incorporated by reference.

### FIELD OF THE INVENTION

The present invention relates to a timer, and more particularly to a timer that can display “run time” and “delay start time” on the same screen.

### BACKGROUND OF THE INVENTION

Conventionally, there are two types of times. One has a display screen, can be operated to start immediately, and once it starts, it cannot be repeated. The other one has numerous time set-up availabilities, which can be start immediately as well. However, these two conventional times cannot display “run time” and “delay start time” on the same screen. Therefore, there remains a need for a new and improved timer to overcome the problems stated above.

### SUMMARY OF THE INVENTION

In one aspect, a timer may include a power plug to connect to a power source, an AC/DC transforming circuit, a relay circuit, a recharging circuit, and a control circuit that includes a relay output, a key input, and an LCD output. The timer may further include a 2.4V battery and a main body.

In one embodiment, the key input may include a plurality of buttons. By pressing one or more of these buttons, signals can be transmitted into the key input of the control circuit. The timer may further include an LCD display and the information displayed thereon is transmitted from the LCD output of the control circuit.

The power plug can be connected to an AC power source to bring in the power to the AC/DC transforming circuit to generate a 12V DC current that can be transmitted to the recharging circuit to charge the 2.4V battery, as well as providing power to the relay circuit.

The 2.4V battery is configured to provide power to the control circuit. The key input of the control circuit receives the signals from one or more buttons, which are processed and output to the LCD display through the LCD output for the user. It is noted that at the present stage, the replay output is configured to control the relay circuit to control the power output of the timer, to perhaps disconnect the power input from the power plug.

When the 2.4V battery is fully charged, the replay output is configured to control the relay circuit to disconnect the power input from the power plug. When the control circuit is powered, the LCD display can display information transmitted from the LCD output. The LCD display can be divided into the following portions: (1) TIMER ON/TIMER OFF; (2) REPEAT ON/REPEAT OFF; (3) RANDOM; (4) DELAY START; and (5) RUN TIME. The abovementioned portions can be controlled through five different buttons: TIMER, REPEAT, RANDOM, DELAY START and RUN TIME. When in use, the user can press either of these buttons to transmit the signals to the key input, and the signals can be processed, and the information thereof can be displayed on the LCD display. Furthermore, the signal to control the relay circuit can be sent out through the relay output.

The power plug can be connected to an AC power source to bring in the power to the AC/DC transforming circuit to generate a 12V DC current that can be transmitted to the recharging circuit to charge the 2.4V battery, as well as providing power to the relay circuit. Meanwhile, the signal for relay output can be used to control the power output to achieve the goal of automated control.

### BRIEF DESCRIPTION OF THE DRAWINGS

FIG. 1 is a schematic view of the block diagram of the timer in the present invention.

### DETAILED DESCRIPTION OF THE INVENTION

The detailed description set forth below is intended as a description of the presently exemplary device provided in accordance with aspects of the present invention and is not intended to represent the only forms in which the present invention may be prepared or utilized. It is to be understood, rather, that the same or equivalent functions and components may be accomplished by different embodiments that are also intended to be encompassed within the spirit and scope of the invention.

Unless defined otherwise, all technical and scientific terms used herein have the same meaning as commonly understood to one of ordinary skill in the art to which this invention belongs. Although any methods, devices and materials similar or equivalent to those described can be used in the practice or testing of the invention, the exemplary methods, devices and materials are now described.

All publications mentioned are incorporated by reference for the purpose of describing and disclosing, for example, the designs and methodologies that are described in the publications that might be used in connection with the presently described invention. The publications listed or discussed above, below and throughout the text are provided solely for their disclosure prior to the filing date of the present application. Nothing herein is to be construed as an admission that the inventors are not entitled to antedate such disclosure by virtue of prior invention.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

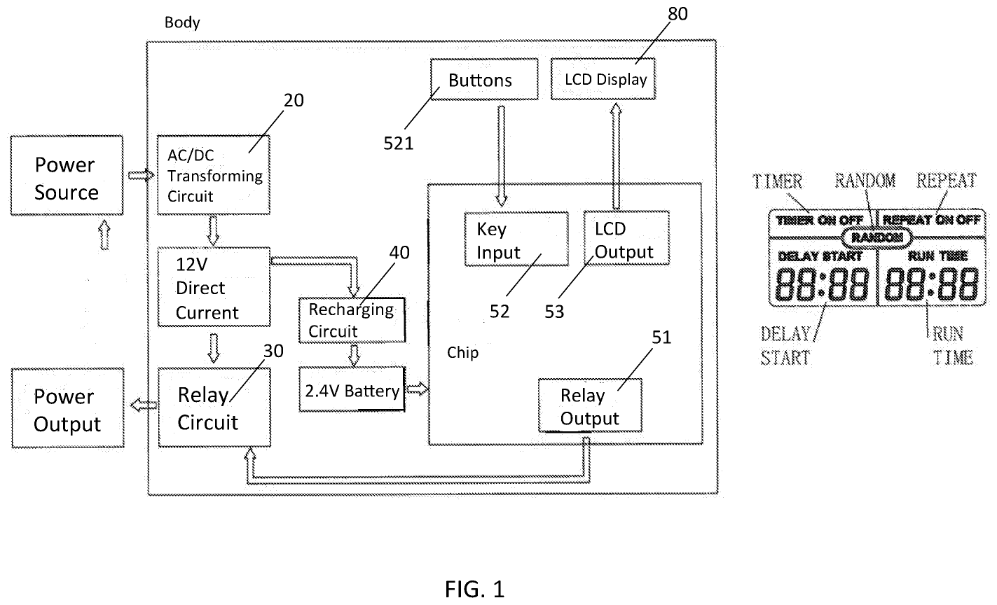

In one aspect, a timer shown in FIG. 1 may include a power plug 10 to connect to a power source, an AC/DC transforming circuit 20, a relay circuit 30, a recharging circuit 40, and a control circuit 50 that includes a relay output 51, a key input 52, and an LCD output 53. The timer may further include a 2.4V battery 60 and a main body 70.

In one embodiment, the key input 52 may include a plurality of buttons 521. By pressing one or more of these buttons 521, signals can be transmitted into the key input 52 of the control circuit 50. The timer may further include an LCD display 80 and the information displayed thereon is transmitted from the LCD output 53 of the control circuit.

The power plug 10 can be connected to an AC power source to bring in the power to the AC/DC transforming circuit 20 to generate a 12V DC current that can be transmitted to the recharging circuit 40 to charge the 2.4V battery, as well as providing power to the relay circuit 30.

The 2.4V battery is configured to provide power to the control circuit 50. The key input 52 of the control circuit 50 receives the signals from one or more buttons 521, which are processed and output to the LCD display 80 through the LCD output 53 for the user. It is noted that at the present stage, the replay output 51 is configured to control the relay circuit 30 to control the power output of the timer, to perhaps disconnect the power input from the power plug 10.

When the 2.4V battery is fully charged, the replay output 51 is configured to control the relay circuit 30 to disconnect the power input from the power plug 10. When the control circuit 50 is powered, the LCD display 80 can display information transmitted from the LCD output 53. The LCD display 80 can be divided into the following portions: (1) TIMER ON/TIMER OFF; (2) REPEAT ON/REPEAT OFF; (3) RANDOM; (4) DELAY START; and (5) RUN TIME. The abovementioned portions can be simultaneously displayed on the LCD display 80 and controlled through five different buttons: TIMER, REPEAT, RANDOM, DELAY START and RUN TIME. When in use, the user can press either of these buttons to transmit the signals to the key input 52, and the signals can be processed, and the information thereof can be displayed on the LCD display 80. Furthermore, the signal to control the relay circuit 30 can be sent out through the relay output 51.

The power plug 10 can be connected to an AC power source to bring in the power to the AC/DC transforming circuit 20 to generate a 12V DC current that can be transmitted to the recharging circuit 40 to charge the 2.4V battery, as well as providing power to the relay circuit 30. Meanwhile, the signal for relay output 51 can be used to control the power output to achieve the goal of automated control.

Having described the invention by the description and illustrations above, it should be understood that these are exemplary of the invention and are not to be considered as limiting. Accordingly, the invention is not to be considered as limited by the foregoing description, but includes any equivalent.

What is claimed is:

1. A timer comprising a power plug to connect to a power source, an AC/DC transforming circuit, a relay circuit, a recharging circuit, and a control circuit that includes a relay output, a key input, an LCD output and an LCD display,
wherein the key input may include a plurality of buttons. By pressing one or more of these buttons, signals can be transmitted into the key input of the control circuit, and the information displayed thereon is transmitted from the LCD output of the control circuit,
wherein the LCD display is divided into the following portions: (1) TIMER ON/TIMER OFF; (2) REPEAT ON/REPEAT OFF; (3) RANDOM; (4) DELAY START; and (5) RUN TIME, and the above fie portions are simultaneously displayed.

2. The timer of claim 1, the timer further comprises a 2.4V battery and a main body.

3. The timer of claim 2, wherein the power plug is connected to an AC power source to bring in the power to the AC/DC transforming circuit to generate a 12V DC current that can be transmitted to the recharging circuit to charge the 2.4V battery, as well as providing power to the relay circuit.

4. The timer of claim 3, wherein the five portions (1) TIMER ON/TIMER OFF; (2) REPEAT ON/REPEAT OFF; (3) RANDOM; (4) DELAY START; and (5) RUN TIME are controlled through five different buttons: TIMER, REPEAT, RANDOM, DELAY START and RUN TIME, which can be pressed to transmit the signals to the key input, and the signals can be processed, and the information thereof can be displayed on the LCD display.
